(19) United States
(12) Patent Application Publication
(10) Pub. No.: US 2010/0032651 A1
(43) Pub. Date: Feb. 11, 2010

(54) QUANTUM DOT INFRARED PHOTODETECTOR

(75) Inventors: Toshihiro Okamura, Shibuya (JP); Mitsuhiro Nagashima, Suginami (JP); Michiya Kibe, Sagamihara (JP); Ryo Suzuki, Kawasaki (JP); Yasuhito Uchiyama, Kawasaki (JP); Hironori Nishino, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: TECHNICAL RESEARCH & DEVELOPMENT INSTITUTE MINISTRY OF DEFENSE OF JAPAN, Tokyo (JP); FUJITSU LIMITED, Kawasaki-shi (JP)

(21) Appl. No.: 12/534,220

(22) Filed: Aug. 3, 2009

(30) Foreign Application Priority Data
Aug. 8, 2008 (JP) 2008-205277

(51) Int. Cl. H01L 31/101

(52) U.S. Cl. 257/21; 977/954; 977/774; 257/E31.054

(57) ABSTRACT

A quantum dot infrared photodetector includes a quantum dot structure including intermediate layers, and a quantum dot layer sandwiched between the intermediate layers and including quantum dots whose energy potential is low for carriers, the intermediate layers and the quantum dots being formed of a III-V compound semiconductor with the V element being As, and an AlAs layer being provided on one of the interfaces between the intermediate layers and the quantum dot layer including the quantum dots and covering at least the quantum dots.

### CROSS REFERENCE TO RELATED APPLICATIONS

This application is based upon and claims the benefit of priority of the prior Japanese Patent Application No. 2008-205277, filed on Aug. 8, 2008, the entire contents of which are incorporated herein by reference.

### FIELD

The embodiments discussed herein are related to an infrared photodetector for detecting infrared radiation, more specifically, a quantum dot infrared photodetector which detects photoelectric current generated by the electrons or holes in the quantum dots excited by application of infrared radiation.

### BACKGROUND

Presently, as a photodetector which detects light by capturing current which flows by the absorption of incident light, the QDIP (Quantum Dot Infrared Photodetector), which can absorb vertically incident light by using quantum dots and can three-dimensionally confine carriers, is noted rather than the QWIP (Quantum Well Infrared Photodetector), which cannot absorb vertically incident light.

As for the QDIP structure, the InAs/GaAs-based QDIP device using GaAs as the intermediate layer and InAs as the quantum dots is much studied because the sensitivity is in the infrared radiation range, and the quantum dots which three-dimensionally confine carriers can be relatively easily formed by self-organization by MBE (Molecular Beam Epitaxy) or others (refer to, e.g., Japanese Laid-open Patent Publication No. 10-256588).

### SUMMARY

Accordingly, it is an object in one aspect of the embodiments is to provide a quantum dot infrared photodetector having the detection sensitivity of detecting infrared radiation more improved.

According to one aspect of the embodiments, a quantum dot infrared photodetector includes a quantum dot structure including intermediate layers, and a quantum dot layer sandwiched between the intermediate layers and including quantum dots whose energy potential is low for carriers, the intermediate layers and the quantum dots being formed of a III-V compound semiconductor with the V element being As, and an AlAs layer being provided on one of the interfaces between the intermediate layers and the quantum dot layer including the quantum dots and covering at least the quantum dots.

The object and advantages of the embodiment will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a view explaining the principle constitution of the embodiments;

FIG. 2 is a sectional view illustrating the structure of the quantum dot infrared photodetector according to one embodiment;

FIG. 3 is the energy band view of the quantum dot infrared photodetector according to the embodiment;

FIG. 4 is a graph of the relationships between the AlAs thickness (atom layer) and the infrared radiation sensitivity of the quantum dot infrared photodetector according to the embodiment;

FIG. 5 is sectional views of the quantum dot infrared photodetector according to the embodiment in the steps of the method for manufacturing the quantum dot infrared photodetector (Part 1);

FIG. 6 is sectional views of the quantum dot infrared photodetector according to the embodiment in the steps of the method for manufacturing the quantum dot infrared photodetectord (Part 2);

FIG. 7 is sectional views of the quantum dot infrared photodetector according to the embodiment in the steps of the method for manufacturing the quantum dot infrared photodetector (Part 3);

FIG. 8 is a sectional view illustrating the structure of the proposed quantum dot infrared photodetector;

FIG. 9 is the energy band view illustrating the quantum dot structure of the proposed quantum dot infrared photodetector; and

FIG. 10 is the energy band views illustrating the overlap of the wave functions at the transition base and the transition destination of the proposed quantum dot infrared photodetector.

### DESCRIPTION OF EMBODIMENTS

### Proposed Quantum Dot Infrared Photodetector

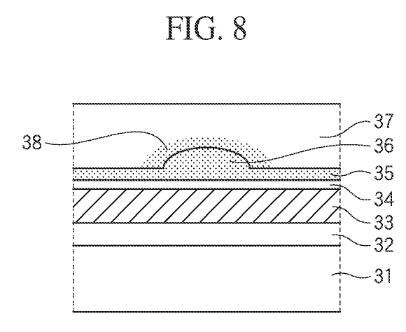

Before the quantum dot infrared photodetector according to the embodiment is explained, for comparison with the embodiment, a quantum dot infrared photodetector which has been already proposed will be explained with reference to FIGS. 8 to 10.

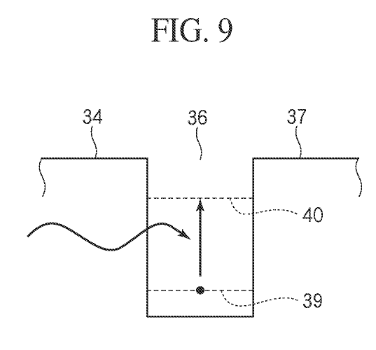

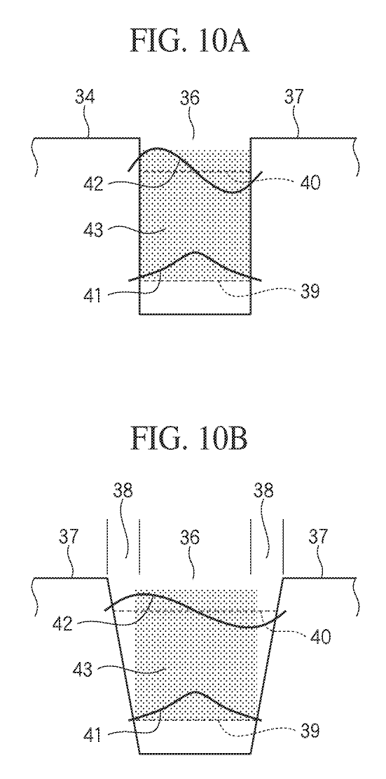

FIG. 8 is a sectional view of the proposed quantum dot infrared photodetector, which illustrates the structure. FIG. 9 is the energy band view illustrating the quantum dot structure of the proposed quantum dot infrared photodetector. FIG. 10 is energy band views illustrating the overlap of the wave functions at the transition base and the transition destination of the proposed quantum dot infrared photodetector.

As illustrated in FIG. 8, the proposed InAs/GaAs-based quantum dot infrared photodetector includes an n-GaAs contact layer 33 and a GaAs barrier layer 34 formed on a GaAs substrate 31 with a GaAs buffer layer 32 formed therebetween, and then In and As are fed by MBE.

At this time, first, early in the growth, an InAs wet layer 35 is grown, taking over the crystal structure of the GaAs buffer layer 32, by the self-organization phenomena of Stranski-Krastanov crystal growth mode using lattice strains of the semiconductor layer structure.

Furthermore, when In and As are fed on by MBE, a rearrangement takes place from the plane structure so as to mitigate the energy of the strains due to the lattice constant difference from the base material, and three-dimensional InAs quantum dots 36 are formed.

Next, the feed of the InAs is stopped, and Ga and As are fed to grow a GaAs intermediate layer 37 to thereby bury the InAs quantum dots 36.

In FIG. 8, to simplify the explanation, only 1 quantum dot is illustrated, but actually, a number of the quantum dots are formed and stacked in plural layers with the intermediate layers formed respectively therebetween.

FIG. 9 is the energy band view illustrating the quantum dot structure of the proposed quantum dot infrared photodetector. In this InAs/GaAs-based QDIP device, the GaAs barrier layer 34 and the GaAs intermediate layer 37 function as the potential barrier to the energy of the carriers, and the InAs quantum dots 36 function as the potential wells. In each InAs quantum dot 36, two quantum levels, i.e., the base level 39 and the first excited level 40 are discretely formed.

When light corresponding to an energy difference between the two formed quantum levels is incident, the carriers are excited and are detected as a signal current.

The sensitivity of this detector is determined by how many electrons are excited (transit) when one (1) photon is incident, but this probability is determined by the magnitude of the overlap between the wave functions of the transition base and a transition destination. That is, as the overlap between the wave functions is larger, the sensitivity of the detector is higher.

The overlap of the wave functions between the transition base and a transition destination is larger when the energy potential structure for the carriers steeply changes, i.e., when the hetero interface which is the barrier layer/the well layer interface steeply changes, and preferably, the hetero interface steeply changes.

However, the inventors of the present application made earnest studies and concluded that in the above-described InAs/GaAs-based quantum dot structure, which is the general combination, because Ga and In easily mutually diffuse, in burying the InAs dots with GaAs, mixed crystallization with the GaAs to be the intermediate layer takes place. Resultantly, the change of the energy potential for the carrier near the interface between the quantum dots and the intermediately layer is made smooth. Accordingly, the inventors conclude that the overlap of the wave functions between the transition base and a transition destination reduces, and the detection sensitivity of the QDIP device is low.

FIG. 10 is the energy band views illustrating the overlap of the wave functions between the transition base and a transition destination of the proposed quantum dot infrared photodetector. FIG. 10A is for the steep interface between the quantum dots and the intermediate layer, and FIG. 10B is for the smooth interface between the quantum dots and the intermediate layer.

As shown in FIG. 10A, in the case that the interface is steep, the overlap between the wave function 41 at the base level 39 and the wave function 42 at the first excitation level 40 is large, and the infrared ration detection sensitivity is high. In the drawing, the number 43 indicates the overlap region of the wave functions.

On the other hand, as shown in FIG. 10B, in the case that Ga and In mutually diffuse, a mixed crystallized region 38 is formed, and the interface is smooth, the wave function at the first excited level 40 spreads in space, which makes small the overlap of the wave function 41 at the base level 39 over the wave function 42 at the first excited level 40, and the infrared radiation detection sensitivity decreases.

As described above, the proposed quantum dot infrared photodetector has a problem that with the interface between the quantum dots and the intermediate layer being smooth, the infrared radiation detection sensitivity is decreased.

The embodiments have been made to prevent the mutual diffusion of the elements forming the quantum dots and the intermediate layers of the proposed quantum dot infrared photodetector to thereby make steep the interface between the quantum dots and the intermediate layers so as to improve the infrared radiation detection sensitivity.

### Principle of the Embodiment

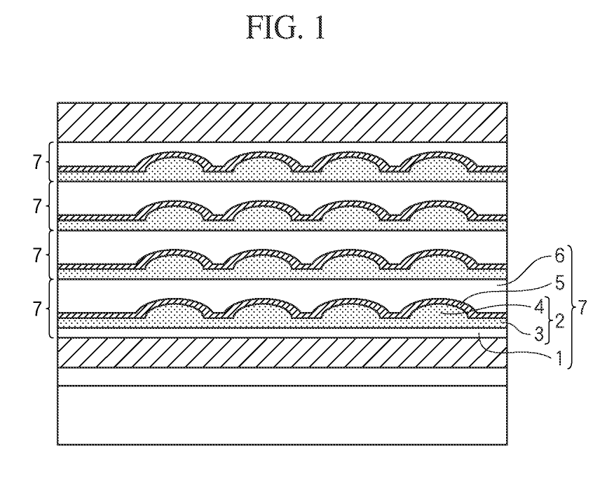

The principle of the embodiment will be explained with reference to FIG. 1 illustrating the principle constitutional view of the embodiment.

The embodiment is a quantum dot infrared photodetector including quantum dot structures 7 each including intermediate layers 1, 6, and a quantum dot layer 2 which includes quantum dots 4 whose energy potential for the carriers is low, and is characterized in that the intermediate layers 1, 6 and the quantum dots 4 are formed of a III-V compound semiconductor whose V element is As, and an AlAs layer 5 is formed on one of the interfaces of each quantum dot structure 7 between the intermediate layers 1, 6 and the quantum dot layer 2 including the quantum dots 4, covering at least the quantum dots 4 is provided.

Generally, the diffusion coefficiency of In for AlAs is smaller than the diffusion coefficiency of In for GaAs. The AlAs layers 5 are provided, covering at least the quantum dots 4, whereby the generation of the mixed crystallization regions is suppressed, and the intermediate layers 1, 6 and the quantum dots 4 interfaces can be retained steep, which can increase the detection sensitivity.

In this case, the quantum dot layers 2 may be formed only of the quantum dots 4. Typically, however, the quantum dot layers 2 are each formed of quantum dots 4 formed by Stranski-Krastanov crystal growth mode as is the quantum dot layers 2, and a wet layer 3. In this case, the wet layer 3 is also covered by the AlAs layer 5.

The thickness of the AlAs layer must be below a thickness which permits the carriers to tunnel.

When the intermediate layers 1, 6 are formed entirely of AlAs, the AlAs becomes the barrier to the carriers injected from the contact, and the sensitivity is lowered, and the detection wavelength deviates from a required wavelength.

To detect 10 μm range infrared radiation, the intermediate layers 1, 6 are typically formed of either of GaAs or AlGaAs. The quantum dot layer 2 is typically formed of InₓGa₁₋ₓAs (0<x≦1).

The quantum dot structure 7 is preferably repeatedly stacked, whereby the photocurrent can be increased corresponding to layer numbers.

According to the embodiment, the quantum dots are covered by the AlAs layer before buried by the intermediate layer, whereby the intermediate layer/the quantum dots interface can be retained steep, which can suppress the decrease of the overlap of the wave functions between quantum level, and accordingly, the sensitivity of the detector can be improved.

A practical example of the embodiment is a 10 μm band infrared photodetector, but the semiconductor material forming the quantum dots is changed, whereby the embodiment is applicable to the near infrared photodetector. Especially, the embodiment relates to a quantum dot infrared photodetector characterized in the constitution which suppresses the diffusion of quantum dot constituent materials forming the quantum dot infrared photodetector using subband transitions.

### One Embodiment

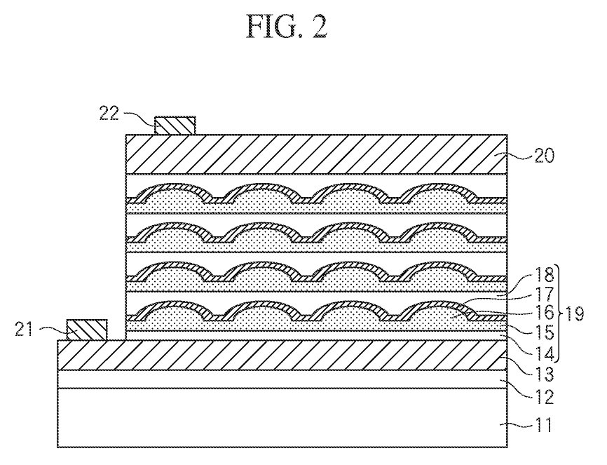

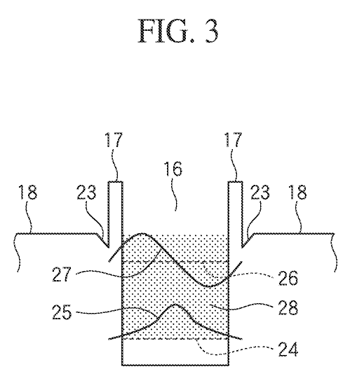

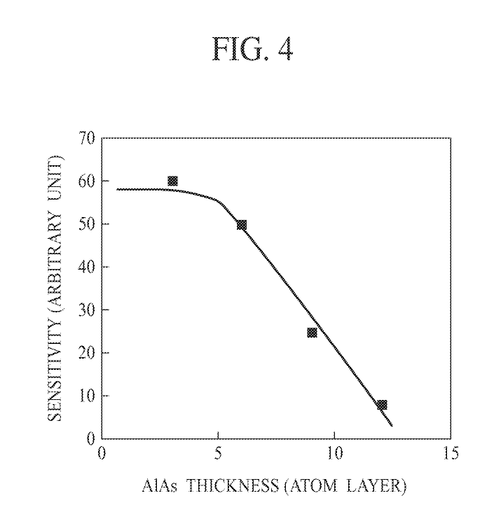

The QDIP (Quantum Dot Infrared Photodetector) according to one embodiment will be explained with reference to FIGS. 2 to 4. FIG. 2 is a sectional view of the quantum dot infrared photodetector according to the present embodiment, which illustrates the structure. FIG. 3 is the energy band view of the quantum dot infrared photodetector according to the present embodiment. FIG. 4 is the graph of the relationships between the AlAs thickness (atom layer) and the infrared ration sensitivity of the quantum dot infrared photodetector according to the present embodiment.

As illustrated in FIG. 2, in the infrared photodetector according to the embodiment, an i-GaAs buffer layer 12 of, e.g., a 100 nm thickness, and an n-GaAs lower contact layer 13 of, e.g., a 250 nm thickness and a 1×10¹⁸ cm⁻³ Si concentration are formed on a semi-insulating GaAs substrate 11 whose primary surface is (100).

On the n-GaAs lower contact layer 13, a non-doped i-GaAs barrier layer 14 of, e.g., a 50 nm thickness is formed. On the i-GaAs barrier layer 14, a wet layer 15 of InAs grown two-dimensionally in plane and having a thickness corresponding to 2-3 atom layers, and a quantum dot layer including quantum dots 16 of InAs grown three-dimensionally in isles are formed. An AlAs diffusion prevention layer 17 corresponding to 1 atom layer of AlAs is formed, and furthermore thereon, a non-doped i-GaAs barrier layer 18 of, e.g., 50 nm thickness is formed.

Thereon, the quantum dot layer including the wet layer 15, the quantum dot layer including quantum dots 16, the AlAs diffusion prevention layer 17 and the i-GaAs barrier layer 18 are formed repeatedly, e.g., 3 times to form a quantum dot structure 19.

On the quantum dot structure 19, an n-GaAs upper contact layer 20 of, e.g., a 150 nm thickness and a 1×10¹⁸ cm⁻³ Si concentration is formed.

On the n-GaAs lower contact layer 13, an electrode 21 of AuGe/Ni/Au is formed, and an electrode 22 of AuGe/Ni/Au is formed on the n-GaAs upper contact layer 20.

Then, the quantum dot structure of the quantum dot infrared photodetector according to the embodiment will be explained with reference to FIG. 3.

In the embodiment, because of the AlAs diffusion preventing layer 17, mixed crystallization regions 23 are not substantially formed, and the hetero interface can be steep.

Accordingly, the overlap of the wave function 25 at the base level 24 and the wave function 27 at the first excitation level 26 becomes large, and the sensitivity is increased. The number 28 schematically indicates the region where the wave functions overlap each other.

The thickness of the AlAs diffusion prevention layer 17 is 1 atom layer, whereby the electrons tunnel the AlAs diffusion preventing layer 17 to transit, and the AlAs diffusion prevention layer 17 does not function as the potential barrier to the electrons.

The thickness of the AlAs diffusion prevention layer 17 is one (1) atom layer, whereby the energy potential structure of the InAs/GaAs quantum dot structure to the electrons never largely changes, and the present embodiment can have high sensitivity to the 10 μm band infrared radiation.

The thickness of the AlAs diffusion prevention layer 17 is one (1) atom layer, which causes no problem in the crystallinity when the AlAs diffusion prevention layer 17 is grown at the substrate temperature of 500° C. as in the InAs growth step, and the AlAs growth step does not affect the InAs quantum dots already formed.

The AlAs diffusion prevention layer 17 may not be one (1) atom layer as long as the electrons can tunnel the AlAs diffusion prevention layer 17 and has no problem in the crystallinity when low temperature grown.

FIG. 4 shows the relationships of the AlAs thickness (atom layer) and the infrared radiation sensitivity of the quantum dot infrared photodetector according to the present embodiment.

As shown in FIG. 4, it is found that with the thickness of the AlAs diffusion prevention layer 17 being about five (5) atom layers, sufficient infrared radiation sensitivity is provided. With the thickness of the AlAs diffusion prevention layer 17 being too large, the sensitivity is affected and is lowered.

Incidentally, when the entire GaAs barrier layer is replaced by an AlAs barrier layer or an AlGaAs barrier layer, for a prescribed crystallinity of a prescribed film thickness, the growth temperature of the barrier layer must be above 600° C. including 600° C., which affects the InAs quantum dots already formed.

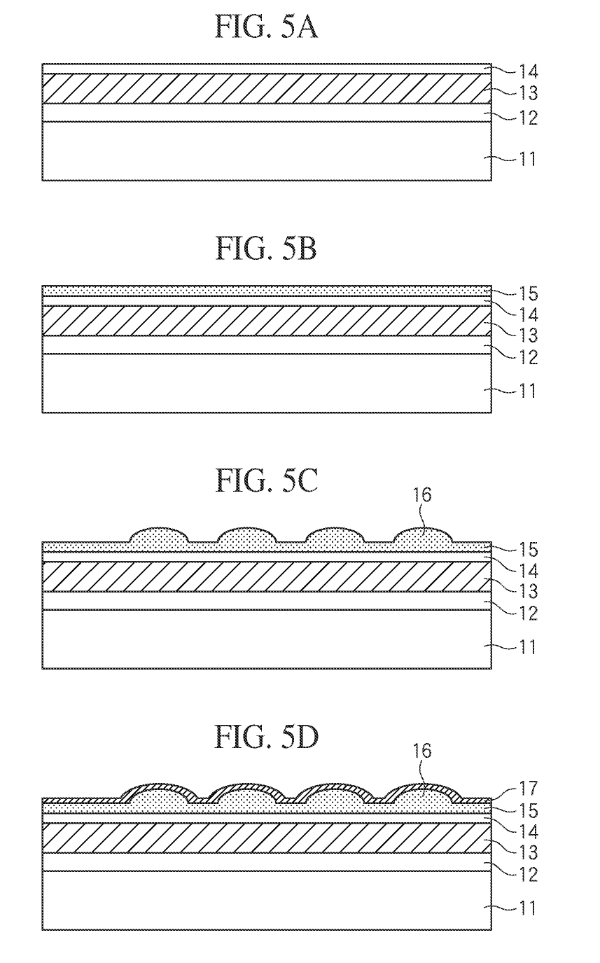

Next, the method for manufacturing the quantum dot infrared photodetector according to the embodiment will be explained with reference to FIGS. 5 to 7.

As illustrated in FIG. 5A, the semi-insulating GaAs substrate 11 having the (100) primary surface is loaded into the substrate introducing chamber of an MBE system. The introduced semi-insulating GaAs substrate 11 is heated to, e.g., 400 C in the introducing chamber to be degassed.

Next, the degassed semi-insulating GaAs substrate 11 is carried into the growth chamber retained in an ultrahigh vacuum of below 10⁻¹⁰ Torr including 10⁻¹⁰ Torr and, in the growing chamber, to remove the oxide film on the surface, is heated to 640° C. in an As atmosphere to be subjected to thermal cleaning.

Next, after the oxide film has been removed, to improve the flatness of the substrate surface, an i-GaAs buffer layer 12 of, e.g., a 100 nm thickness is grown on the semi-insulating GaAs substrate 11 at the substrate temperature of, e.g., 600° C. (FIG. 5A).

Subsequently, an n-GaAs lower contact layer 13 of, e.g., a 250 nm thickness and a 1×10¹⁸ cm⁻³ concentration, and the non-doped i-GaAs barrier layer 14 of, e.g., a 50 nm thickness are sequentially deposited (FIG. 5A).

Then, the substrate temperature is set at, e.g., 500° C. to feed InAs corresponding to a 2-3 atom layers.

At this time, by the initial InAs supply, the InAs two-dimensionally grows flat to form the wet layer 15 (FIG. 5B). By the following InAs supply, the InAs is three-dimensionally grown into isles by strains generated due to the lattice constant difference between GaAs and InAs, and the quantum dots 16 are formed (FIG. 5C). The quantum dots 16 are formed in an about 10-50 nm diameter, an about 2-8 nm height and an about 10¹⁰ pieces/cm²-10¹¹ pieces/cm² density.

Then, with the growth temperature kept at 500° C., the feed of the InAs is stopped, and AlAs is fed in, e.g., one (1) atom layer to growth the AlAs diffusion prevention layer 17, covering the quantum dots 16 (FIG. 5D).

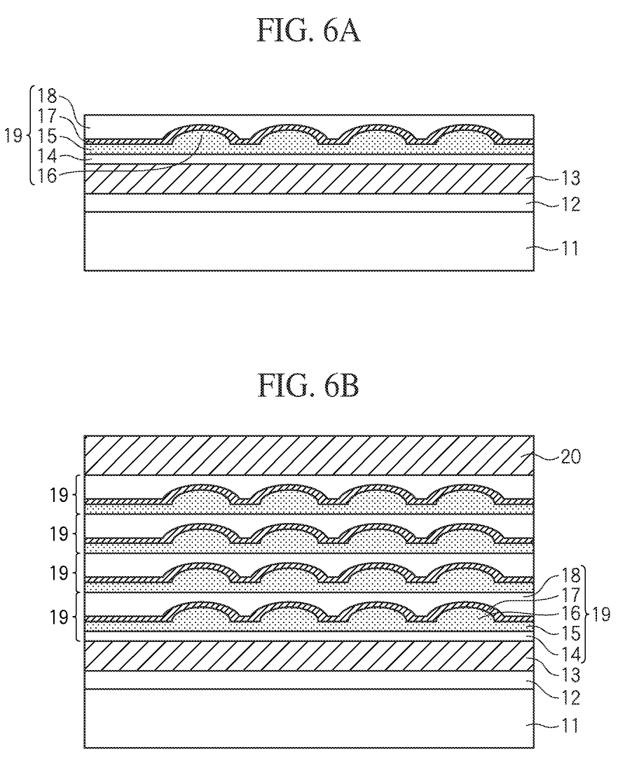

Subsequently, the feed of the AlAs is stopped, and GaAs is fed to grow the non-doped i-GaAs barrier layer 18 of, e.g., a 50 nm thickness to bury the quantum dots 16 (FIG. 6A).

Hereafter, these steps are repeated for a required layer number, e.g., three times to grow totally four (4) quantum dot structures 19. Then, the substrate temperature is raised to 600° C. to deposit the n-GaAs upper contact layer 20 of, e.g., a 150 nm-thickness and a 1×10¹⁸ cm⁻³ Si concentration (FIG. 6B).

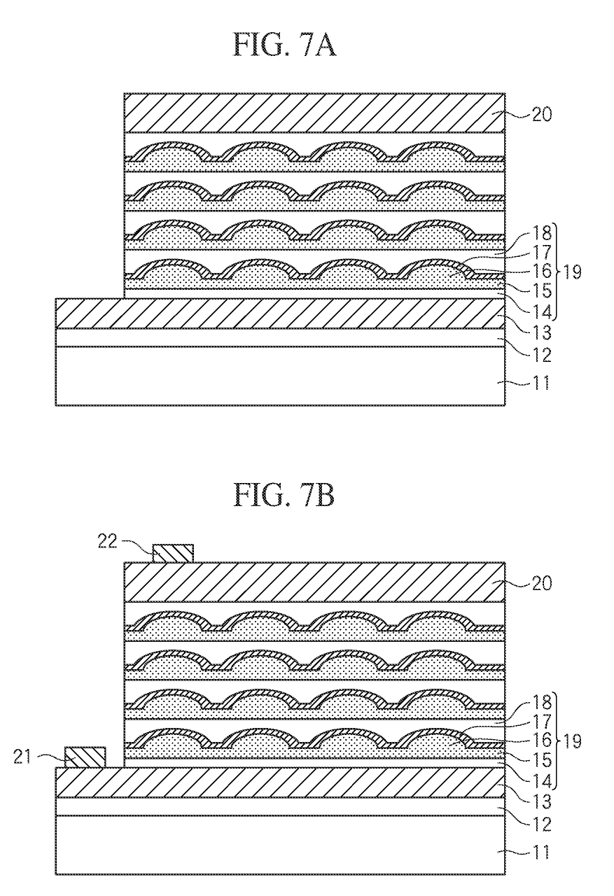

Then, by lithography and dry etching, the n-GaAs upper contact layer 20 to the i-GaAs barrier layer 14 are partially selectively etched to expose a part of the surface of the n-GaAs lower contact layer 13 (FIG. 7A).

Next, the electrodes 21, 22 of AuGe/Ni/Au are formed on the upper and the lower contact layers by metal vapor deposition, and the basic structure of the quantum dot infrared photodetector according to the present embodiment is completed (FIG. 7B).

### Modified Embodiments

The embodiments are not limited to the above-described embodiment and can cover other various modifications.

For example, in the above-described embodiment, the quantum dots are formed of InAs. However, InAs is not essential, and other semiconductors, such as InGaAs, etc., can be used and can be selected suitably for a wavelength of the infrared radiation to be detected.

In the above-described embodiment, the barrier layer is formed of GaAs. However, the barrier layer can be formed of AlGaAs and may be formed of layer structures of these plural materials.

In the above-described embodiment, the quantum dots are formed by molecular bean epitaxial growth. However, the molecular beam epitaxial growth is not essential, and other crystal growth methods, e.g., MOCVD (Metal Organic CVD), etc., may be used.

In the above-described embodiment, the substrate for the crystal growth is GaAs. However, the substrate may be InP, and in this case, the barrier layer may be formed of InGaAlAs, which lattice-matches with InP.

In the above-described embodiment, the layer number of the quantum dot structure is 4. The quantum dot structure may have multi-layers, as of 8-10 layer structures. Otherwise, oppositely the quantum dot structure may have a single layer. The layer number is arbitrary.

In the above-described embodiment, the quantum dot layer includes quantum dots by the SK crystal growth mode, and the wet layer. The quantum dot layer may include quantum dots alone without the wet layer. The quantum dot layer of the quantum dots alone can be grown, depending on combinations of the materials of the barrier layer and the quantum dots, the growth method and growth conditions.

In the above-described embodiment, the inter-sub-band transitions in the quantum dots on the conduction band side are used, i.e., the carriers detecting light are electrons. The carriers detecting light are not limited to electrons. The embodiment is applicable to QDIP devices using the inter-sub-band transitions in the quantum dots on the valence electron band side.

According to the embodiments, the intermediate layers and the quantum dots are formed of a III-V compound semiconductor with the V element being As, and the AlAs layer is provided on one of the interface between the intermediate layers and the quantum dot layer including the quantum dots and covering at least the quantum dots, whereby the mutual diffusion of the element forming the quantum dots and the intermediate layers can be prevented so as to make the quantum dot/the intermediate layer interface steep to thereby improve the detection sensitivity of infrared radiation.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A quantum dot infrared photodetector including a quantum dot structure including intermediate layers, and a quantum dot layer sandwiched between the intermediate layers and including quantum dots whose energy potential is low for carriers,
the intermediate layers and the quantum dots being formed of a III-V compound semiconductor with the V element being As, and
an AlAs layer being provided on one of the interfaces between the intermediate layers and the quantum dot layer including the quantum dots and covering at least the quantum dots.

2. A quantum dot infrared photodetector according to claim 1, wherein
the AlAs layer is provided, covering a wet layer forming the quantum dot layer.

3. A quantum dot infrared photodetector according to claim 1, wherein
the thickness of the AlAs layer is below a thickness which permits carriers to tunnel.

4. A quantum dot infrared photodetector according to claim 1, wherein
the intermediate layers are formed of GaAs, AlGaAs or InGaAlAs, and
the quantum dot layer is formed of InₓGa₁₋ₓAs (0<x≦1).

5. A quantum dot infrared photodetector according to claim 1, wherein
the quantum dot structure is repeatedly stacked.
